(19) United States
(12) Patent Application Publication
(10) Pub. No.: US 2018/0080741 A1
(43) Pub. Date: Mar. 22, 2018

(54) ACTIVE CAMOUFLAGE SYSTEM AND METHOD

(71) Applicant: A. Jacob Ganor, Kowloon (HK)

(72) Inventor: A. Jacob Ganor, Kowloon (HK)

(21) Appl. No.: 15/561,775

(22) PCT Filed: Mar. 25, 2016
(86) PCT No.: PCT/US16/24279

§ 371 Date: Sep. 26, 2017

Related U.S. Application Data
(60) Provisional application No. 62/139,093, filed on Mar. 27, 2015.

(51) Int. Cl. F41H 3/02; H01L 27/32; G02B 1/11; H04N 5/33

(52) U.S. Cl. CPC F41H 3/02; H01L 27/3244; B82Y 20/00; H04N 5/332; G02B 1/11

(57) ABSTRACT

An active camouflage system includes one or more imaging devices that are engageable to a first side of a subject and that is to detect a visual image, which can be visual and/or thermal. A display assembly includes of at least one display segment and is engageable to a second side of the subject. An active camouflage controller is in communication with the imaging device and the display assembly to receive a visual image; prepare a camouflage image based at least in part on the visual image; and display the camouflage image on the display assembly.

### CROSS-REFERENCE TO RELATED APPLICATIONS

The present Application for Patent claims priority to U.S. Provisional Application No. 62/139,093, entitled “ACTIVE CAMOUFLAGE SYSTEM AND METHOD,” filed Mar. 27, 2015, and hereby expressly incorporated by reference herein.

### BACKGROUND OF THE INVENTION

### 1. Field of the Invention

The field of art disclosed herein pertains to active camouflage systems and method, and more particularly for visual and thermal optimized active camouflage.

### 2. Description of the Related Art

Conventional military camouflage is passive; modern camouflage uniforms employ disruptive patterns and countershading to mimic the dappled textures and rough boundaries found in natural and urban settings. An example of the current state of the art which possesses all of the above mentioned attributes is the U.S. Marine Corps MARPAT camouflage uniform, which comprises a fractal pattern of pixel like squares and rectangles designed to blend a subject into its background.

### SUMMARY OF THE INVENTION

In one aspect, the present disclosure provides an active camouflage system including one or more imaging devices that are engagable to a first side of a subject and that is to detect a visual image. A display assembly is comprised of at least one display segment and that is engageable to a second side of the subject. An active camouflage controller is in communication with the imaging device and the display assembly to: receive a visual image; prepare a camouflage image based at least in part on the visual image; and display the camouflage image on the display assembly.

In another aspect, the present disclosure provides a method of manufacturing an active camouflage system. In one or more embodiments the method includes attaching a synthetic sapphire glass cover to an active-matrix organic light emitting diode (AMOLED) display screen. The method includes attaching an anti-reflective coating to the sapphire glass cover to form a display segment. The method includes attaching the display segment to a first side of a substrate that is attachable around a subject. The method includes attaching an imaging device on an opposing second side of the substrate.

In an additional aspect, the present innovation provides method of actively camouflaging a subject. In one or more embodiments, the method includes attaching more than one display segment on a subject that present different planar vantage points on a first side of the subject. The method includes detecting from an opposing side of the subject visual images that corresponds to the respective planar vantage points. The method includes causing the display segments respectively to display respective camouflage images that correspond to the visual images.

These and other features are explained more fully in the embodiments illustrated below. It should be understood that in general the features of one embodiment also may be used in combination with features of another embodiment and that the embodiments are not intended to limit the scope of the invention.

### BRIEF DESCRIPTION OF THE DRAWINGS

The various exemplary embodiments of the present invention, which will become more apparent as the description proceeds, are described in the following detailed description in conjunction with the accompanying drawings, in which:

FIG. 1 illustrates a conceptual diagram of an active camouflage system, according to one or more embodiments:

FIG. 2 illustrates a diagram of an example active camouflage system for multiple vantage point targets, according to one or more embodiments;

FIG. 3 illustrates an example active camouflage system that is incorporated into a body suit, according to one or more embodiments;

FIG. 4 illustrates a functional block diagram of a controller of an active camouflage system, according to one or more embodiments:

FIG. 5 illustrates a flow diagram of a method of manufacturing an active camouflage system, according to one or more embodiments; and

FIG. 6 illustrates a method of actively camouflaging a subject, according to one or more embodiments.

### DETAILED DESCRIPTION

Theoretical analysis reveals that this aim can be better obtained by dynamically matching the object to be camouflaged to its background colors and light levels thus rendering it virtually invisible to the eye. In one or more embodiments, the present innovation can address aspects of implementing active camouflage by utilizing wearable high-contrast ratio screens connected to visible light and infrared cameras, light sensors, and three dimensional depth sensors. In one or more embodiments, the present innovation can address aspects of at least partially resolving potential issues with respect to viewing angle and parallax, resulting in a three dimensional active camouflage effect. In one or more embodiments, the present innovation can address aspects of applying this active camouflage technique to infrared wavelengths in addition to visible light. In one or more embodiments, the present innovation can address aspects of applying this active camouflage concept to ground and aerial vehicles. Other objects and a fuller understanding of the innovation may be ascertained from the following description and claims.

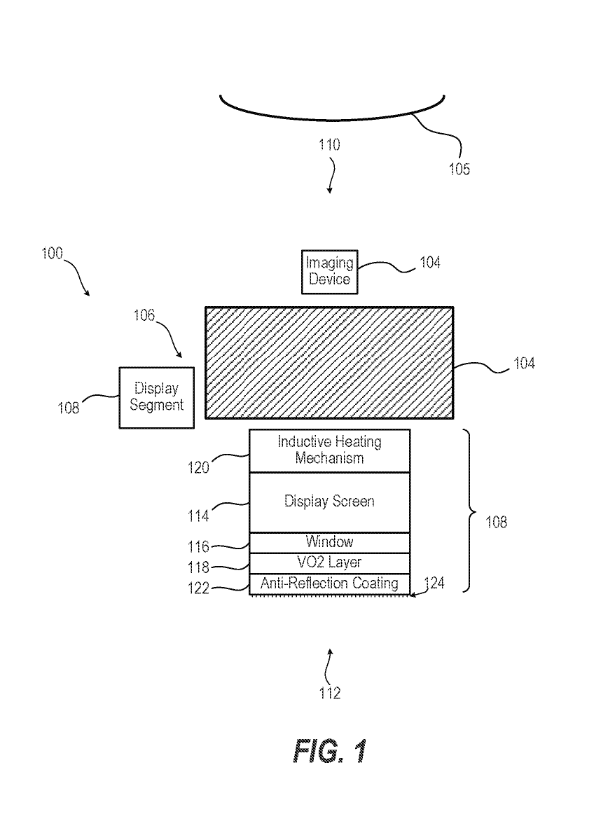

FIG. 1 illustrates an active camouflage system 100 includes one or more imaging devices 102 that are engagable to a first side of a subject 104 and that is to detect a visual image 105. A display assembly 106 includes one or more display segments 108 that are engageable to a second side of the subject 102. The first side can be a rear side 110 and the second side can be a front side 112. The display segment 108 includes a display screen 114 that is protected by a transparent window 116. In one or more embodiments, the display segment 108 includes a vanadium (IV) oxide (VO₂) layer 118. An inductive heating mechanism 120 can heat the transparent window 116 and the VO₂ layer 118 to change an apparent thermal signature of the display segment 108. The display segment 108 can also include an anti-reflection coating 122. Alternatively or in addition, an exterior surface of the display segment 108 can include a “moth eye” nanotextured layer 124 of cones.

Several methods are available for the fabrication of an active camouflage device. In one instance: Square shaped or hexagonal high contrast OLED or E-ink screens of 1-20 cubic inches in area are obtained. In one or more embodiments, the display screen 114 can be an active-matrix organic light emitting diode (AMOLED) display screen. AMOLED is a display technology for use in mobile devices and television. OLED describes a specific type of thin-film-display technology in which organic compounds form the electroluminescent material, and active matrix refers to the technology behind the addressing of pixels. An AMOLED display consists of an active matrix of OLED pixels that generate light (luminescence) upon electrical activation that have been deposited or integrated onto a thin-film-transistor (TFT) array, which functions as a series of switches to control the current flowing to each individual pixel. Typically, this continuous current flow is controlled by at least two TFTs at each pixel (to trigger the luminescence), with one TFT to start and stop the charging of a storage capacitor and the second to provide a voltage source at the level needed to create a constant current to the pixel, thereby eliminating the need for the very high currents required for passive-matrix OLED operation. TFT backplane technology is one aspect in the fabrication of AMOLED displays. The two primary TFT backplane technologies, namely polycrystalline silicon (poly-Si) and amorphous silicon (a-Si), are used today in AMOLEDs. These technologies offer the potential for fabricating the active-matrix backplanes at low temperatures (below 150° C.) directly onto flexible plastic substrates for producing flexible AMOLED displays.

The exterior surfaces of these display screens 114 are made of a rugged and durable transparent material. This can encompass high hardness ceramics and treated glass such as sapphire, transparent spinel ceramic, or chemically toughened glass coated with optically transparent silicon dioxide (SiO₂) films or ductile materials such as toughened plastic. Sapphire is an exemplary example of a display screen 114. Synthetic sapphire refers not to the amorphous state, but to the transparency. Sapphire is not only highly transparent to wavelengths of light between 150 nm (UV) and 5500 nm (IR) (the human eye can discern wavelengths from about 380 nm to 750 nm), but is also extraordinarily scratch-resistant. Sapphire has a value of 9 on the Mohs scale of mineral hardness. Benefits of synthetic sapphire glass include (i) very wide optical transmission band from UV to near-infrared, (0.15-5.5 μm), (ii) significantly stronger than other optical materials or standard glass windows, highly resistant to scratching and abrasion, and (iii) extremely high melting temperature (2030° C.). Sapphire glass refers to crystalline sapphire used as an optical window or cover. Some windows are made from pure sapphire boules that have been grown in a specific crystal orientation, typically along the optical axis, the c-axis, for minimum birefringence for the application. The boules are sliced up into the desired window thickness and finally polished to the desired surface finish. Sapphire optical windows can be polished to a wide range of surface finishes due to its crystal structure and its hardness. The surface finishes of optical windows are normally called out by the scratch-dig specifications in accordance with the globally adopted MIL-O-13830 specification.

In instances where sapphire as the transparent window 116 is used to ruggedize the display screen 114, the sapphire glass can optionally be coated with a layer of vanadium (IV) oxide (VO₂) of twenty five to four hundred nanometers in thickness to form the VO₂ layer 118. In this case, the bezels of each individual screen can be connected to the induction heating mechanism 120, which can rapidly modulate the heat of the sapphire screen. Thin films of VO₂ deposited over sapphire glass display highly unusual infrared optical properties due solely to an atypical interaction between the VO₂ film and the sapphire substrate when the VO₂ is heated to an intermediate state of its insulator metal transition. This response is widely tunable; i.e., as the thin film is heated past a certain threshold, its degree of thermal emission decreases; heated to temperatures past approximately 80° C., sapphire glass treated with a VO₂ thin film starts emitting less thermal radiation and appears much colder on an infrared camera. This has clear implications for an active camouflage system, particularly as many modern weapons systems rely on infrared imaging to acquire targets. Being able to actively shift the black body radiation curve of the camouflaged object allows it to blend into its surroundings or project non identifiable shapes, and this, in turn, allows for a degree of active infrared camouflage well in advance of the current state of the art. Optionally, these screens are then anti reflection treated. This can encompass single layer anti reflection coatings, multi-layer anti reflection coatings, or nanotextured anti-reflection structures.

In a particular embodiment, an exemplary use in the present innovation can include the anti-reflection coating 122 that is a multilayer interference structure, in which transparent materials with different refractive indexes are deposited in one dimension over the ruggedized screen surface.

To further improve performance of an anti-reflection coating 122, a “moth eye nanotextured layer 124 can be included, in which the surface is covered with a two-dimensional array of cones which have a period and height of several hundred nanometers. This texturing, in addition to improving anti-reflective performance, has the added benefit of increasing hydrophobicity and water resistance.

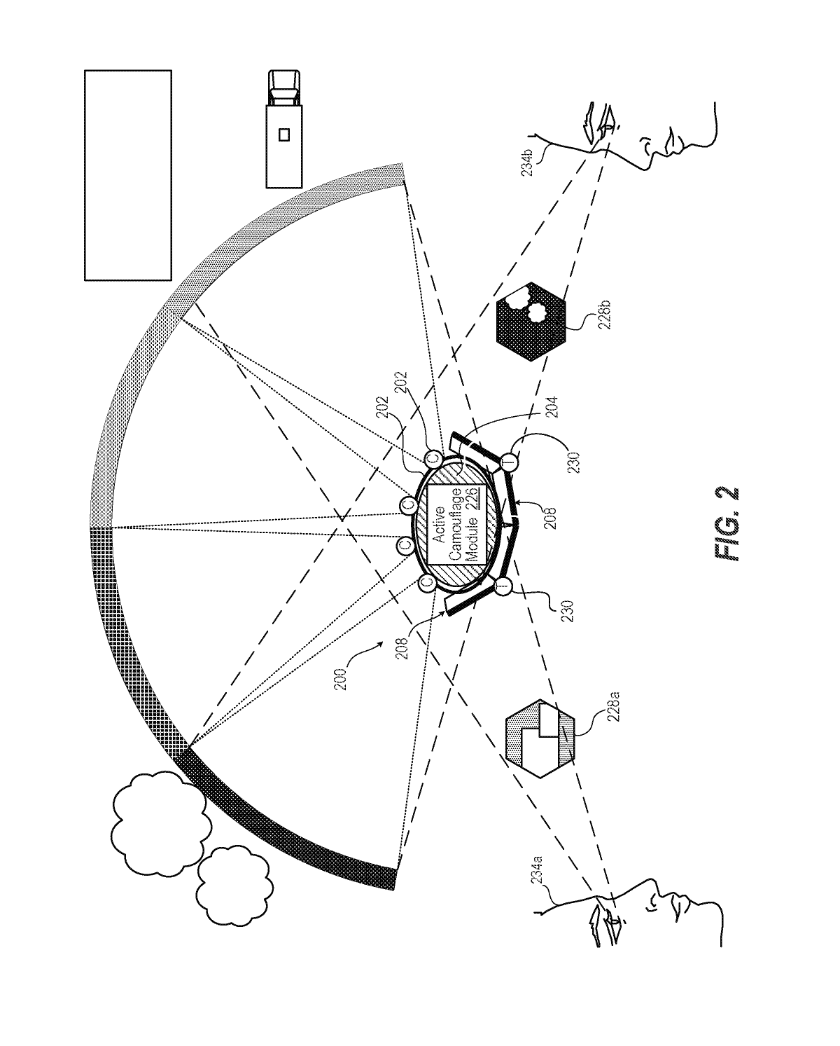

FIG. 2 illustrates an active camouflage system 200 of display segments 208 that are hexagonal or square to form a substantially continuous display assembly 206, even when affixed or coupled to a nonplanar subject 204. Each display segment 208 is tangentially engageable in a first geometric plane to the subject 204 and a second display segment 208 that is tangentially engageable in a second geometric plane to the subject 204 that is not parallel or aligned to the first geometric plane. Imaging devices 202 are to detect a respective first and second visual image 205a. 205b that are perpendicular to the first and second display segments 208. An active camouflage module 226 is to display a respective first and second camouflage images 228a. 228b on the first and second display segments 208.

These display segments 208 can be arranged in a wearable grid, ideally hexagonal or square, with cameras and sensors located at junctions where the screens meet. Each screen can be given a coordinate, and each input camera/sensor can project to single coordinate or a set of coordinates.

Ambient light sensors, preferentially between screens and located at screen junctions, can also project to a coordinate or set of coordinates. These sensors would match screen output to ambient light settings, thus allowing the camouflaged object to blend into its surroundings without seeming to emit light. The screens, with input from the cameras and depth sensors, can be programmed to display an abstract pattern pixel array, based on the colors and features of the landscape, and this pattern can be refreshed either manually or on an arbitrary timed basis, e.g. every 10 or 30 minutes. Alternatively, these cameras and sensors can be programmed to present the observer with the scene that the camouflaged object is blocking out, thus presenting a translucent effect. This effect where cameras on the camouflage system user's rear project their image to the front, and cameras on the front project to the rear can be displayed in real time and refreshed at 30 frames per second or faster. Tracking sensors 230 such as depth sensor can be used to track the motion of nearby people and vehicles, and can be programmed to alter the displayed images/scenes/pattern based on their predicted viewing angle. For example, the active camouflage system 200 can detect first and second targets 234a. 234b. This may help to prevent potential parallax issues.

In certain manifestations of the above invention, parallax issues can be further ameliorated via the use of lenticular screens.

When trying to camouflage a shape with sharp angles, e.g. a vehicle, lenticular screens can be used to blend light input from the corners of the vehicle when the vehicle is not directly in front of its viewers, thus masking its outline and providing a quasi 3D active camouflage effect.

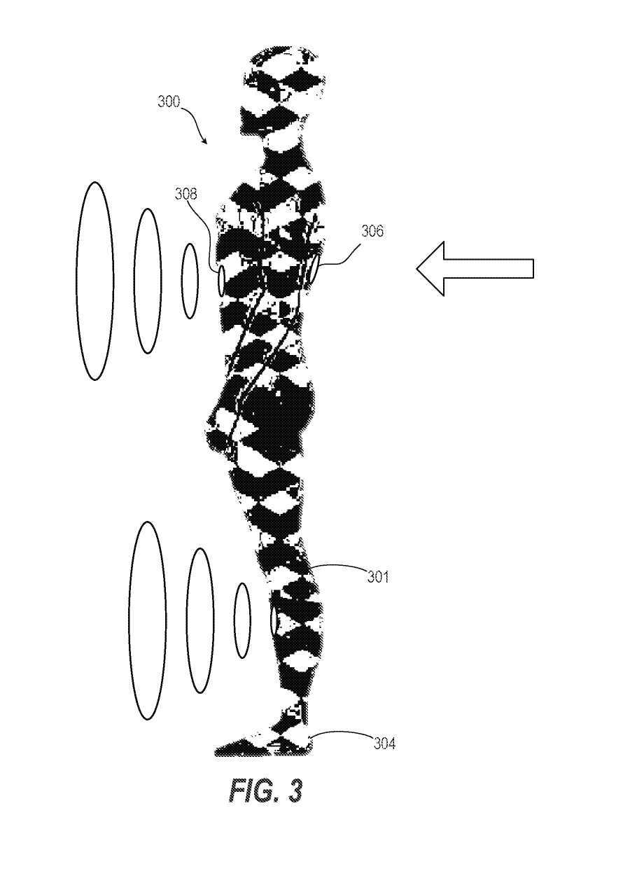

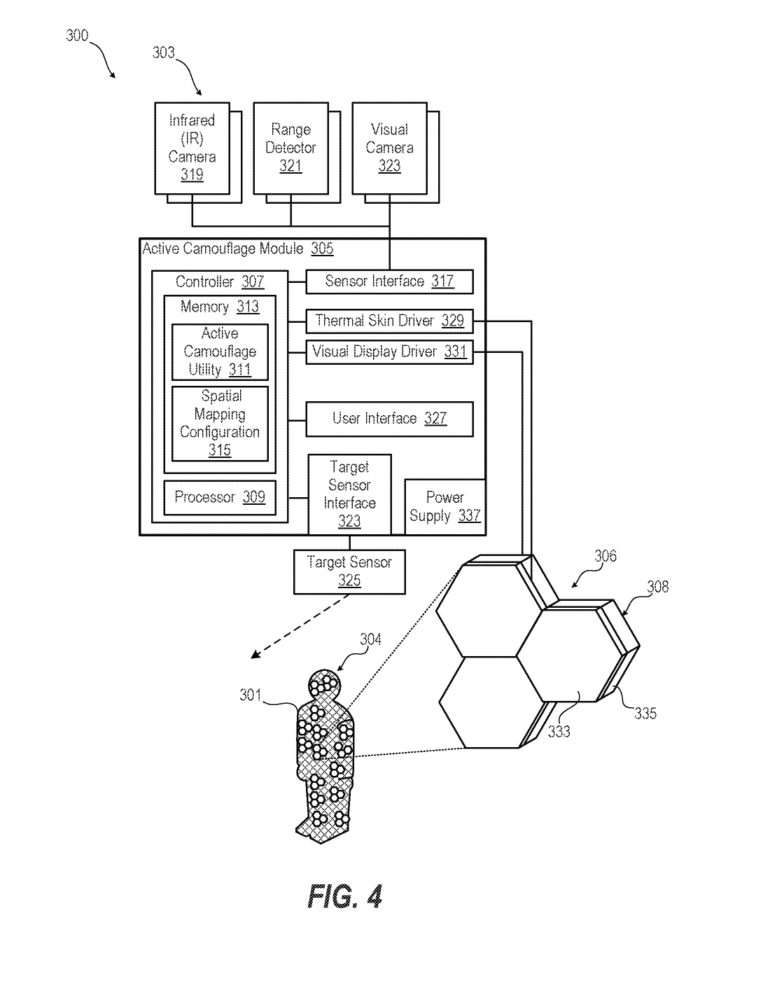

FIGS. 3-4 illustrate an exemplary active camouflage system 300 that is incorporated in a body suit 301 as a substrate for positioning sensor 303 and display segments 308 of a display assembly 306 on a user 304. FIG. 4 illustrates the exemplary active camouflage system 300 including an active camouflage module 305 having a controller 307 that executes on a processor 309 an active camouflage utility 311 that is resident in memory 313 and draws upon spatial mapping configuration 315 to convert received imagery to camouflage imagery. To that end, a sensor interface 317 receives data from infrared (IR) cameras 319, range detectors 321, and visual cameras 323. A target sensor interface 323 communicates with a target sensor 325. A user interface 327 interacts with a user of the active camouflage system 300. A thermal skin driver 329 controls thermal layer 331 of the display segments 308. A visual display driver 333 controls a visual display 335 of the display segments 308, a power supply 337 can provide portable power to the active camouflage module 305.

The devices described above can be feasibly powered with commercially available batteries including, but not limited to, lithium ion batteries, nickel zinc batteries, and others known to those with an ordinary skill in the art. When used in land or aerial vehicles, these devices can be powered by either standalone batteries or integrated electrical systems, e.g. automobile accessory power. The devices described above can be manufactured with the use of commercially available processors and memory.

FIG. 5 illustrates a method 500 of manufacturing an active camouflage system. In one or more embodiments, the method 500 includes attaching a synthetic sapphire glass cover to an AMOLED display screen (block 502). The method 500 includes attaching an anti-reflective coating to the sapphire glass cover to form a display segment (block 504). The anti-reflective coating can be a single-layer anti-reflective coating, a multiple-layer anti-reflective coating comprising layers of differing indexes of refraction, and/or a moth eye nanotexture of cones attached to the sapphire glass cover. The method 500 includes attaching the display segment to a first side of a substrate that is attachable around a subject (block 506). The method 500 includes attaching an imaging device on an opposing second side of the substrate (block 508). The substrate can be a wearable outer garment or an outer surface of a vehicle.

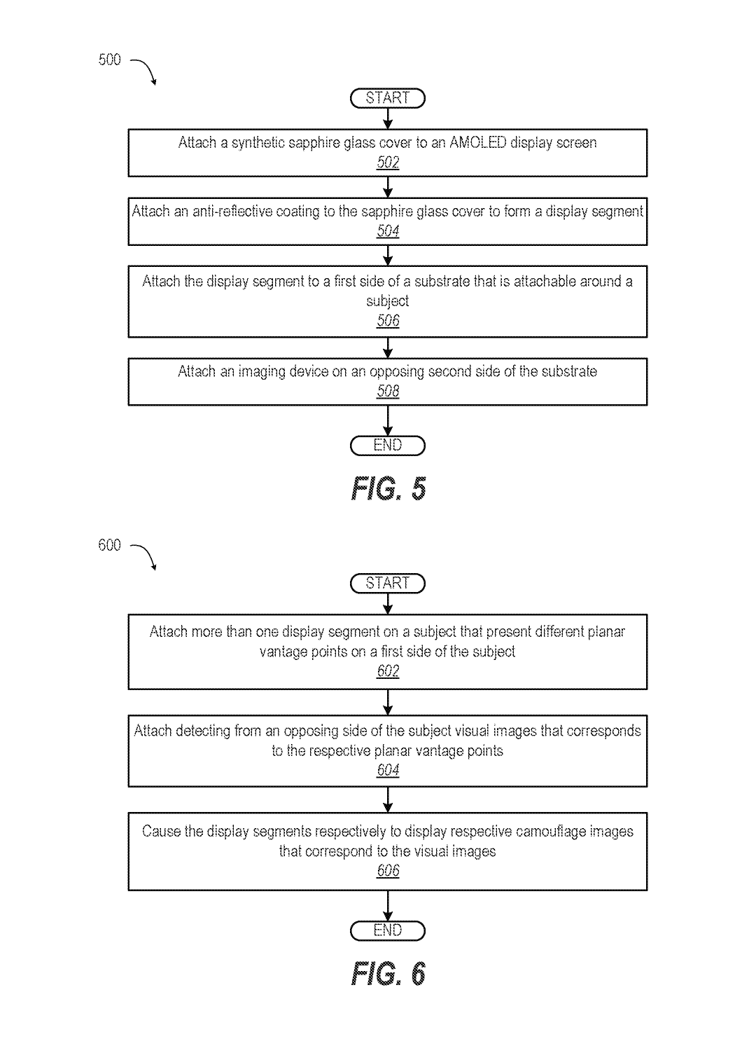

FIG. 6 illustrates a method 600 of actively camouflaging a subject. In one or more embodiments, the method 600 includes attaching more than one display segment on a subject that present different planar vantage points on a first side of the subject (block 602). The method 600 includes detecting from an opposing side of the subject visual images that corresponds to the respective planar vantage points (block 604). The method 600 includes causing the display segments respectively to display respective camouflage images that correspond to the visual images (block 606).

In the above described flow charts of FIGS. 5-6, the method may be embodied in an automated manufacturing system or a controller respectively that performs a series of functional processes. In some implementations, certain steps of the methods are combined, performed simultaneously or in a different order, or perhaps omitted, without deviating from the scope of the disclosure. Thus, while the method blocks are described and illustrated in a particular sequence, use of a specific sequence of functional processes represented by the blocks is not meant to imply any limitations on the disclosure. Changes may be made with regards to the sequence of processes without departing from the scope of the present disclosure. Use of a particular sequence is therefore, not to be taken in a limiting sense, and the scope of the present disclosure is defined only by the appended claims.

It must be noted that, as used in this specification and the appended claims, the singular forms “a,” “an” and “the” include plural referents unless the content clearly dictates otherwise. Thus, for example, reference to a “colorant agent” includes two or more such agents.

Unless defined otherwise, all technical and scientific terms used herein have the same meaning as commonly understood by one of ordinary skill in the art to which the invention pertains. Although a number of methods and materials similar or equivalent to those described herein can be used in the practice of the present invention, the preferred materials and methods are described herein.

As will be appreciated by one having ordinary skill in the art, the methods and compositions of the invention substantially reduce or eliminate the disadvantages and drawbacks associated with prior art methods and compositions.

It should be noted that, when employed in the present disclosure, the terms “comprises.” “comprising,” and other derivatives from the root term “comprise” are intended to be open-ended terms that specify the presence of any stated features, elements, integers, steps, or components, and are not intended to preclude the presence or addition of one or more other features, elements, integers, steps, components, or groups thereof.

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure.

While it is apparent that the illustrative embodiments of the invention herein disclosed fulfill the objectives stated above, it will be appreciated that numerous modifications and other embodiments may be devised by one of ordinary skill in the art. Accordingly, it will be understood that the appended claims are intended to cover all such modifications and embodiments, which come within the spirit and scope of the present invention.

What is claimed is:

1. An active camouflage system comprising:
one or more imaging devices that are engagable to a first side of a subject and that is to detect a visual image;
a display assembly that is comprised of at least one display segment and that is engageable to a second side of the subject; and
an active camouflage controller that is in communication with the imaging device and the display assembly to:
receive a visual image;
prepare a camouflage image based at least in part on the visual image; and
display the camouflage image on the display assembly.

2. The active camouflage system of claim 1, wherein the display assembly comprises an active-matrix organic light emitting diode (AMOLED) display.

3. The active camouflage system of claim 1, wherein the display assembly comprises an anti-reflective coating.

4. The active camouflage system of claim 1, wherein the display assembly comprises a nanotexturized exterior layer.

5. The active camouflage system of claim 1, wherein the display assembly comprises a synthetic sapphire glass cover.

6. The active camouflage system of claim 5, wherein:
the visual image comprises an infrared image;
the display assembly comprises:
a vanadium (IV) oxide (VO₂) layer of twenty five to four hundred nanometers in thickness that is attached to the synthetic sapphire glass cover the; and
an induction heating mechanism to selectively heat the synthetic sapphire glass cover and the VO₂ layer; and
the active camouflage controller displays the camouflage image on the display assembly by causing the induction heating mechanism to heat the synthetic sapphire glass cover and the VO₂ layer to an internal temperature that corresponds to an external temperature of the infrared image.

7. The active camouflage system of claim 1, wherein:
the first side of the subject is nonplanar;
the display assembly comprises a first display segment that is tangentially engageable in a first geometric plane to the subject and a second display segment that is tangentially engageable in a second geometric plane to the subject that is not parallel or aligned to the first geometric plane;
the more than one imaging device is to detect a respective first and second visual image that is perpendicular to the first and second display segments;
the active camouflage controller is to display a respective first and second camouflage image on the first and second display segments.

8. A method of manufacturing an active camouflage system, the method comprising:
attaching a synthetic sapphire glass cover to an active-matrix organic light emitting diode (AMOLED) display screen;
attaching an anti-reflective coating to the sapphire glass cover to form a display segment;
attaching the display segment to a first side of a substrate that is attachable around a subject;
attaching an imaging device on an opposing second side of the substrate.

9. The method of claim 8, further comprising attaching the anti-reflective coating by attaching a single-layer anti-reflective coating.

10. The method of claim 8, further comprising attaching the anti-reflective coating by attaching a multiple-layer anti-reflective coating comprising layers of differing indexes of refraction.

11. The method of claim 8, further comprising attaching the anti-reflective coating by attaching a moth eye nanotexture of cones to the sapphire glass cover.

12. The method of claim 8, wherein the substrate comprises a wearable outer garment.

13. A method of actively camouflaging a subject, the method comprising:
attaching more than one display segment on a subject that present different planar vantage points on a first side of the subject;
detecting from an opposing side of the subject visual images that corresponds to the respective planar vantage points; and
causing the display segments respectively to display respective camouflage images that correspond to the visual images.
